(19) United States
(12) Patent Application Publication
(10) Pub. No.: US 2022/0384542 A1
(43) Pub. Date: Dec. 1, 2022

(54) Display Panel, Manufacturing Method Thereof and Display Apparatus

(71) Applicant: BOE Technology Group Co., Ltd., Beijing (CN)

(72) Inventors: Guoying WANG, Beijing (CN); Zhen SONG, Beijing (CN)

(21) Appl. No.: 17/043,719

(22) PCT Filed: Mar. 31, 2020
(86) PCT No.: PCT/CN2020/082325

§ 371 Date: Sep. 30, 2020

(30) Foreign Application Priority Data
May 31, 2019 (CN) 201910472480.4

(51) Int. Cl. H01L 27/32; H01L 51/56; H01L 51/52

(52) U.S. Cl. CPC H01L 27/3246; H01L 51/56; H01L 51/5228; H01L 2227/323; H01L 2251/558

(57) ABSTRACT

The present invention provides a display panel, a manufacturing method thereof and a display apparatus. The display panel includes a substrate, a light-emitting element, and a pixel defining layer. The light-emitting element includes a cathode, an anode and a light-emitting layer, the pixel defining layer defines a plurality of openings, the light-emitting layer is disposed in the openings and covers a predetermined area on a side of the pixel defining layer facing towards the openings, and hydrophilicity of the pixel defining layer at each position of the predetermined area is substantially identical.

### CROSS-REFERENCE TO RELATED APPLICATIONS

The present application is a U.S. National Phase Entry of International Application No. PCT/CN2020/082325 having an international filing date of Mar. 31, 2020, which claims the benefit of Chinese Patent Application No. 201910472480.4, filed with the Chinese Patent Office on May 31, 2019, both of which are hereby incorporated by reference in their entirety.

### TECHNICAL FIELD

The present invention relates to the field of display technology, in particular to a display panel, a manufacturing method thereof and a display apparatus.

### BACKGROUND

Currently, an organic light-emitting diode (OLED) display panel is one of the hottest in the field of display technology, an aperture ratio of which may reach 100% in theory, which is beneficial to the integration of devices and integrated circuits. In another word, a focus on the study of an active-matrix organic light-emitting diode (AM-OLED) is required in the future preparation of a large-size and high-solution display panel. In a display panel with an active-matrix organic light-emitting diode, a light-emitting layer is mainly manufactured by ink-jet printing and the like. However, on one hand, when the light-emitting layer is manufactured by the ink-jet printing, the manufactured light-emitting layer is always prone to bend, which leads to poor uniformity of the thickness of the light-emitting layer. In severe cases, the ink for forming the light-emitting layer may even overflow from openings defined by a pixel defining layer of the active-matrix organic light-emitting diode, which in turn leads to poor brightness uniformity of the light emitted from the light-emitting layer when in use, resulting in a phenomena of electric leakage and brightness in the periphery of a pixel unit, and thereby resulting in poor display effect. On the other hand, when the display panel in related arts is in use, the problem of IR drop in the display panel is still severe, which affects the display performances.

Therefore, the related technology of the existing display panel still needs to be improved.

### SUMMARY

In one aspect of the present invention, the present invention provides a display panel. According to an embodiment of the invention, the display panel includes a substrate, a light-emitting element and a pixel defining layer. The light-emitting element includes a cathode, an anode and a light-emitting layer. The pixel defining layer defines a plurality of openings. The light-emitting layer is disposed in the openings and covers a predetermined area on a side of the pixel defining layer facing towards the openings. Hydrophilicity at each position of the predetermined area is substantially identical. The expression “hydrophilicity at each position of the predetermined area is substantially identical” may be rephrased as that: the hydrophilicity of the pixel defining layer at each position of the predetermined area is substantially identical. In the display panel, there is no problem of surface hydrophilicity and hydrophobicity being different in the predetermined area. Therefore, the light-emitting layer in the display panel may not bend after manufacture, and the uniformity of the thickness of the light-emitting layer is high, so that the brightness uniformity of light emitted by the display panel is good, and the problem that the light-emitting layer overflows from the openings during manufacture may not occur. As a result, the phenomenon of electric leakage or the brightness in the periphery of the pixel unit may not occur during the use of the display panel, thereby the display effect of the display panel is good.

According to an embodiment of the present invention, the pixel defining layer includes a first defining layer defining a plurality of the openings, and an insulating dielectric layer disposed on a side of the first defining layer facing towards the openings. At least a part of a side of the insulating dielectric layer facing towards the openings constitutes the predetermined area.

According to an embodiment of the present invention, the display panel further includes an auxiliary cathode disposed on a surface of the cathode close to the substrate, and an inorganic material layer. The inorganic material layer is disposed on a surface of the auxiliary cathode close to the substrate, and a surface of the inorganic material layer away from the auxiliary cathode is in contact with a surface of the first defining layer away from the substrate.

According to an embodiment of the present invention, the insulating dielectric layer is integrally formed with the inorganic material layer.

According to an embodiment of the present invention, materials for forming the insulating dielectric layer and the inorganic material layer each independently include at least one of silicon oxide, silicon nitride and silicon oxynitride.

According to an embodiment of the present invention, thicknesses of the insulating dielectric layer and the inorganic material layer each are independently 1000-4000 Å.

In another aspect of the present invention, the present invention provides a method for manufacturing the aforementioned display panel. According to an embodiment of the present invention, the method includes forming a pixel defining layer defining a plurality of openings on a substrate, providing a predetermined area on a side of the pixel defining layer facing towards the openings, and making hydrophilicity of each position of the predetermined area to be substantially identical (according to the above, it may also be rephrased as making hydrophilicity of the pixel defining layer at each position of the predetermined area to be substantially identical); forming a light-emitting layer in the openings, wherein the light-emitting layer covers the predetermined area, so as to obtain the display panel. The method is simple and convenient to operate, easy to carry out and easy for industrial production. In addition, in the manufactured display panel, the light-emitting layer may not bend after manufacture, and the uniformity of the thickness of the light-emitting layer is high, so that the brightness uniformity of light emitted by the display panel is good, and the problem that the light-emitting layer overflows from the openings during manufacture may not occur. As a result, the phenomenon of electric leakage or the brightness in the periphery of the pixel unit may not occur during the use of the display panel, thereby the display effect of the display panel is good.

According to an embodiment of the present invention, forming the pixel defining layer includes forming a first defining layer on the substrate, where the first defining layer defines a plurality of the openings, and forming an insulating dielectric layer on a side of the first defining layer facing towards the openings. At least a part of a side of the insulating dielectric layer facing towards the openings constitutes the predetermined area.

According to an embodiment of the present invention, the method further includes forming an inorganic material layer on a surface of the first defining layer away from the substrate; forming an auxiliary cathode on a surface of the inorganic material layer away from the first defining layer; and forming a cathode on a surface of the auxiliary cathode away from the substrate.

According to an embodiment of the present invention, the insulating dielectric layer and the inorganic material layer are formed in one step.

In yet another aspect of the present invention, the present invention provides a display apparatus. According to an embodiment of the present invention, the display apparatus includes the aforementioned display panel. The display apparatus when in use does not have the phenomenon of electric leakage or the brightness in the periphery of the pixel unit, so as to have good display effect and all the features and advantages of the display panel described above, which will not be repeated here.

### BRIEF DESCRIPTION OF DRAWINGS

FIG. 1a, FIG. 1b, and FIG. 1c show a schematic flowchart of a method for manufacturing a display panel in the related art.

FIG. 2 shows a schematic diagram of a sectional structure of a display panel according to an embodiment of the present invention.

FIG. 3 shows a schematic diagram of a sectional structure of a display panel according to an embodiment of the present invention.

FIG. 4 shows a schematic diagram of a sectional structure of a display panel according to another embodiment of the present invention.

FIG. 5 shows a schematic diagram of a sectional structure of a display panel according to yet another embodiment of the present invention.

FIG. 6 shows a schematic flowchart of a method for manufacturing a display panel according to an embodiment of the present invention.

FIG. 7a, FIG. 7b, FIG. 7c, FIG. 7d, and FIG. 7e show a schematic flowchart of a method for manufacturing a display panel according to another embodiment of the present invention.

FIG. 8 shows a schematic diagram of a sectional structure of a display apparatus according to one embodiment of the present invention.

### REFERENCE SIGNS

10: display panel; 1, 100: substrate; 110: light shielding layer; 120: buffer layer; 130: gate electrode; 131: drain electrode; 132: source electrode; 133: active layer; 140: gate insulating layer; 150: interlayer insulating layer; 160: protective layer; 170: flat layer; 2: pixel defining layer; 200: first defining layer; 21: acrylic; 22: fluorine-containing resin; 3: ink; 4: nozzle; 5, 303: light-emitting layer; 6, 210: opening; 301: cathode; 302: anode; 400: insulating dielectric layer; 500: auxiliary cathode; 600: inorganic material layer; 700: spacer wall; 710: planarization layer; 720: black matrix; 730: color filter; 800: cover glass

### DETAILED DESCRIPTION

Description will now be made in detail to embodiments of the present invention. Embodiments described below are exemplary and are intended to explain the present invention, and should not be construed as limiting the present invention. If specific technologies or conditions are not indicated in the embodiments, it shall be carried out according to the technologies or conditions described in the literature in the art or according to the product specification. The reagents or instruments used without indicating the manufacturers are conventional products that may be obtained commercially.

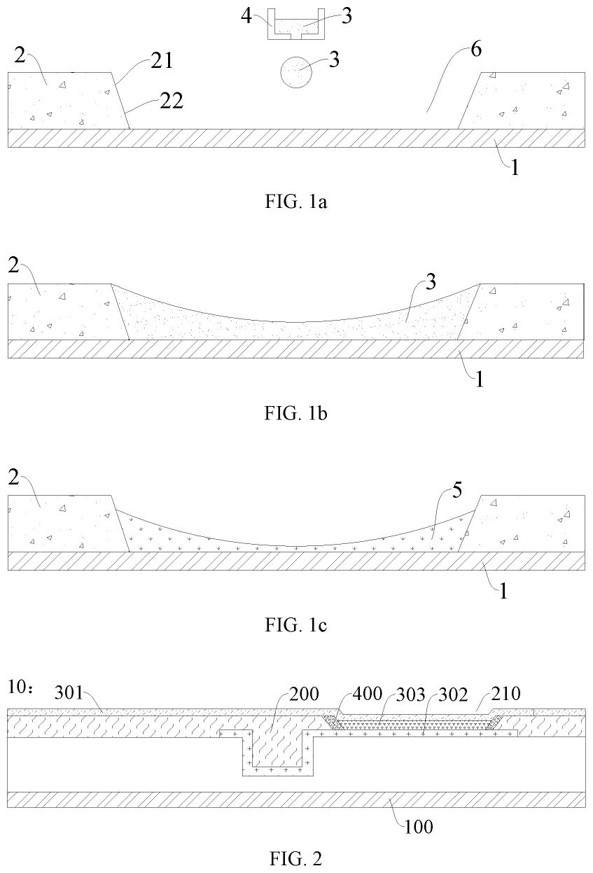

The present invention is made on the basis of the following findings of the inventors. In a first aspect, the inventors of the present invention have made an in-depth research and extensive verification on the reasons why the light-emitting layer manufactured by the ink-jet printing is always prone to bend, resulting in poor uniformity of the thickness of the light-emitting layer, and find that the reason for this phenomenon which exists in the manufacturing method of the related art is as follows. Referring to FIG. 1a, FIG. 1b and FIG. 1c, generally, in a display panel, a pixel defining layer 2 is formed on a surface of the substrate 1 of the display panel (it should be noted that those skilled in the art may understand that there may be other structures between the pixel defining layer 2 and the substrate 1, such as thin film transistors, etc., which are not shown in the figures). At present, the materials for forming the pixel defining layer 2 must contain acrylic 21 and fluorine-containing resin 22. After forming the pixel defining layer 2, the acrylic 21 and fluorine-containing resin 22 may be layered inside the pixel defining layer 2, where the acrylic 21 may be mainly distributed on a side of the fluorine-containing resin 22 away from the substrate in the pixel defining layer 2, which in turn may lead to better hydrophobicity of a part on a surface of side wall of the pixel defining layer away from the substrate, and better hydrophilicity of a part of a surface of the side wall close to the substrate (refer to FIG. 1a for a schematic structural diagram). Therefore, when the light-emitting layer is manufactured by the ink-jet printing, after the ink 3 for forming the light-emitting layer drips from a nozzle 4 into the opening 6 defined by the pixel defining layer 2 (refer to FIG. 1a for a schematic structure diagram when the ink 3 drips into the opening 6), the ink 3 may move along the side wall of the pixel defining layer to the surface with better hydrophilicity (refer to FIG. 1b for a schematic structure diagram, it should be noted that those skilled in the art may understand that there is an anode between the ink 3 or the light-emitting layer 5 and the substrate 1, which is not shown in FIG. 1b and the following FIG. 1c), which leads to the bending phenomenon of the light-emitting layer 5 obtained after solvent evaporation, and leads to poor uniformity of thickness (refer to FIG. 1c for a schematic structural diagram). Those skilled in the art may understand that when the ink droplets formed by the ink 3 are large, the material for forming the light-emitting layer may overflow from the openings, which leads to the phenomenon of electric leakage and the brightness in the periphery of the pixel unit during the use of the display panel.

In another aspect, in related technologies, the resistance of the cathode of the display panel is relatively large, and especially in the large-size display, the problem of IR Drop of the cathode of the display panel is relatively severe. Therefore adding an auxiliary cathode that forms a short-circuit with the cathode is required to reduce the resistance of metal traces in the display panel. In related technologies, in order to solve the problem of relatively severe IR drop in the display panel, it is a common practice to manufacture the auxiliary cathode on a surface of the gate electrode of the thin film transistor in the display panel 10. However, by doing this, an over-coring structure may be formed in the display panel 10 once again, where the over-coring structure may severely affect the aperture ratio of the display panel.

In view of the above problems, the inventors have made an in-depth research on the process for manufacturing the display panel, and find the following. On one hand, in the display panel, the light-emitting layer of the display panel is disposed in the openings and covers the predetermined area on a side of the pixel defining layer facing towards the openings, and hydrophilicity at each position in the predetermined area is made to be substantially identical. In another word, hydrophilicity of the pixel defining layer at each position of the predetermined area being substantially basically is enough to solve the technical problem in the first aspect described above. On the other hand, the position of the auxiliary cathode may be changed and an inorganic material layer may be added in the display panel, which is enough to solve the technical problem in the second aspect described above.

In view of this, an object of the present invention is to provide a display panel with advantages of no bending of the light-emitting layer after manufacture, high uniformity of the thickness of the light-emitting layer, good brightness uniformity of the emitted light, no overflow from the openings during manufacture, no phenomenon of electric leakage or brightness in the periphery of the pixel unit during use, or with good display effect.

In one aspect of the present invention, the present invention provides a display panel. According to an embodiment of the present invention, referring to FIG. 2, the display panel 10 includes a substrate 100, a light-emitting element and a pixel defining layer. The light-emitting element includes a cathode 301, an anode 302 and a light-emitting layer 303. The pixel defining layer defines a plurality of openings 210. The light-emitting layer 303 is disposed in the openings 210 and covers a predetermined area on a side of the pixel defining layer facing towards the openings. Hydrophilicity at each position of the predetermined area is substantially identical. The expression “hydrophilicity at each position of the predetermined area is substantially identical” may be rephrased as that: hydrophilicity of the pixel defining layer at each position of the predetermined area is substantially identical. In the display panel 10, there is no problem of surface hydrophilicity and hydrophobicity being different in the predetermined area. Therefore, the light-emitting layer 303 in the display panel 10 may not bend after manufacture, and the uniformity of the thickness of the light-emitting layer 303 is high, so that the brightness uniformity of light emitted by the display panel 10 is good, and the problem that the light-emitting layer 303 overflows from the openings during manufacture may not occur. As a result, the phenomenon of electric leakage or the brightness in the periphery of the pixel unit may not occur during the use of the display panel 10, thereby the display effect of the display panel 10 is good.

According to an embodiment of the present invention, particularly referring to FIG. 2, the pixel defining layer includes a first defining layer 200 defining a plurality of the openings 210, and an insulating dielectric layer 400 disposed on a side of the first defining layer 200 facing towards the openings 210. At least a part of a side of the insulating dielectric layer 400 facing towards the openings 210 constitutes the predetermined area. As a result, the light-emitting layer 303 is in contact with the insulating dielectric layer 400, instead of the first defining layer 200 with non-uniform surface hydrophilicity. The hydrophilicity at each position on a surface of the insulating dielectric layer 400 away from the first defining layer 200 is substantially identical, which does not have the problem of surface hydrophilicity and hydrophobicity being different. Therefore, the light-emitting layer 303 in the display panel 10 may not bend after manufacture, and the uniformity of the thickness of the light-emitting layer 303 is good, thereby resulting good brightness uniformity of the light emitted by the display panel 10.

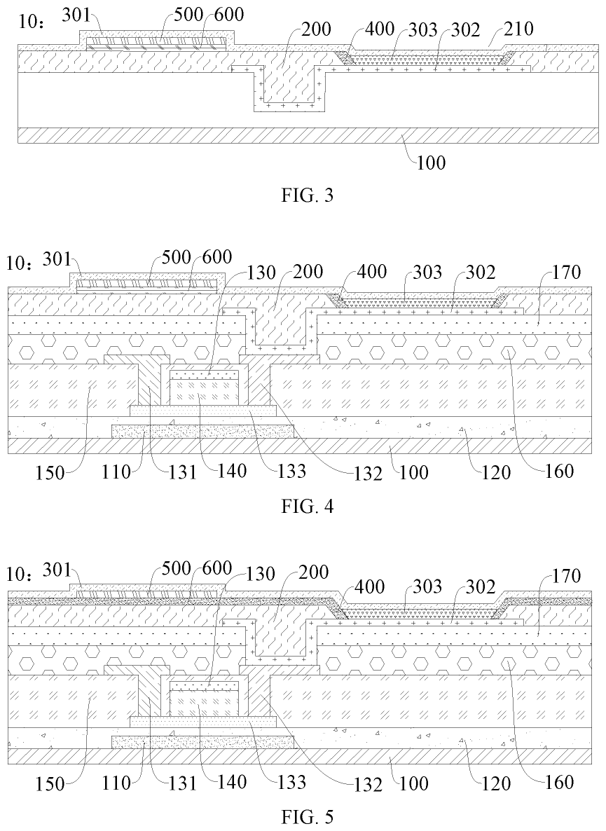

According to an embodiment of the present invention, further referring to FIG. 3, the display panel 10 further includes an auxiliary cathode 500 disposed on a surface of the cathode 301 close to the substrate 100, and an inorganic material layer 600. The inorganic material layer 600 is disposed on a surface of the auxiliary cathode 500 close to the substrate 100, and a surface of the inorganic material layer 600 away from the auxiliary cathode 500 is in contact with a surface of the first defining layer 200 away from the substrate 100. Therefore, the inventors skillfully dispose the auxiliary cathode 500 on a surface of the cathode 301 close to the substrate 100, so that the auxiliary cathode 500 forms a short-circuit with the cathode 301, thereby effectively reducing the resistance of metal traces in the display panel 10 and effectively reducing the IR drop in the display panel 10. In addition, an inorganic material layer 600 is disposed on a surface of the first defining layer 200 away from the substrate 100. The auxiliary cathode 500 is disposed on a surface of the inorganic material layer 600 away from the first defining layer 200. Such an arrangement makes it unnecessary to add an over-coring structure when forming the auxiliary cathode 500 in the display panel 10, which is beneficial to improving the yield of the manufacturing process without affecting the aperture ratio of the display panel. In addition, the manufacturing process is simple and low in cost. Meanwhile, the inorganic material layer 600 is disposed between the auxiliary cathode 500 and the first defining layer 200. Compared with the arrangement that the auxiliary cathode 500 is directly disposed on a surface of the first defining layer 200, since both the auxiliary cathode 500 and the inorganic material layer 600 are formed of inorganic materials, their mutual binding is relatively stable, so that the auxiliary cathode 500 is capable of better functioning to reduce the resistance of the metal traces in the display panel 10, further effectively reducing the IR drop in the display panel 10.

According to an embodiment of the present invention, the materials for forming the auxiliary cathode 500 may be a metal with low resistivity. In particular, the materials may be copper, silver, gold or a stacked structure of the above three metals with other metals. For example, the materials may be a three-layer structure formed by a layer of molybdenum-neodymium alloy, a layer of metal copper, and a layer of molybdenum-neodymium alloy, or alternatively, a stacked structure formed by a layer of indium-tin oxide, a layer of metal, and a layer of indium-tin oxide. Therefore, the materials are widely available and low in cost, which may better function to reduce the resistance of the metal traces in the display panel 10, and further effectively reduce the IR drop in the display panel 10.

According to an embodiment of the present invention, particularly referring to FIG. 4, those skilled in the art may understand that the display panel 10 further includes a light shielding layer 110, a buffer layer 120, and a thin film transistor including a gate electrode 130, a drain electrode 131, a source electrode 132, an active layer 133, a gate insulating layer 140, an interlayer insulating layer 150, a protective layer 160, and a flat layer 170. In the display panel 10, positions of arrangement and connection relationships of the above structures and components are positions of arrangement and connection relationships in a conventional display panel, which will not be repeated here.

According to an embodiment of the present invention, in particular, the light shielding layer 110 may be formed by depositing materials for forming the light shielding layer 110 on a surface of the substrate 100, and then etching is performed to the materials to form the light shielding layer 110. The materials for forming the light shielding layer 110 may include metal or alloy, in particular to molybdenum, aluminum, titanium, gold, copper, hafnium, tantalum, aluminum-neodymium alloy or molybdenum-niobium alloy, and the like. Therefore, the materials are widely available and low in cost.

According to an embodiment of the present invention, the buffer layer 120 may be formed by deposition. The materials for forming the buffer layer may be insulating materials such as silicon oxide, silicon nitride and silicon oxynitride and the like. The active layer 133 is formed by depositing material for forming the active layer 133 on a surface of the buffer layer 120 and etching. The materials for forming the active layer 133 may be IGZO and the like. Therefore, the materials are widely available and low in cost.

According to an embodiment of the present invention, the gate insulating layer 140 and the gate electrode 130 may be formed by firstly depositing and then etching. The materials for forming the gate insulating layer 140 are insulating materials, in particular to silicon oxide, silicon nitride, silicon oxynitride, and the like. The materials for forming the gate electrode 130 may be metal, in particular to molybdenum, aluminum, titanium, gold, copper, hafnium, tantalum, and the like, or may also be formed by multiple layers of metal, for example, a three-layer structure formed by a layer of molybdenum-neodymium alloy, a layer of metal copper and a layer of molybdenum-neodymium alloy. Therefore, the materials are widely available and low in cost.

According to an embodiment of the present invention, the process for forming the interlayer insulating layer 150 may be a conventional process. When the interlayer insulating layer 150 is formed, patterning is performed on its surface to form the drain electrode 131 and the source electrode 132, the specific process for which is a conventional process and will not be repeated here.

According to an embodiment of the present invention, the materials for forming the protective layer 160 and the flat layer 170 are conventional materials, such as SOG (an organic silicon material on glass), BCB (benzocyclobutene) and the like. The forming process is also a conventional process and will not be repeated here.

According to an embodiment of the present invention, the materials for forming the anode 302 may be a metal layer with lower reflectivity and higher refractive index, in particular to indium tin oxide or metallic silver. Alternatively, the materials for forming the anode 302 may be a stacked structure of indium tin oxide and metal layers, for example, a layer of indium tin oxide layer, a layer of metal and a layer of indium tin oxide, which may be formed by direct deposition. Therefore, the materials are widely available and low in cost, resulting better display effect.

According to an embodiment of the present invention, the materials for forming the cathode 301 may be films of transparent conductive oxide (TCO), such as aluminum-doped zinc oxide (AZO), indium zinc oxide (IZO), aluminum-doped tin zinc oxide (AZTO), or a mixture of the above materials. In addition, the materials for forming the cathode 301 may also be metal composite materials, such as manganese-silver composite materials, calcium-silver composite materials, samarium-silver composite materials, aluminum-silver composite materials, barium-silver composite materials, and the like. Therefore, the materials are widely available and low in cost.

According to the embodiments of the present invention, the thicknesses of the above structures may be conventional thicknesses, which will not be repeated here.

According to an embodiment of the present invention, referring to FIG. 5, the insulating dielectric layer 400 is integrally formed with the inorganic material layer 600. As a result, since the insulating dielectric layer 400 is integrally formed with the inorganic material layer 600, on one hand, the process for manufacturing the insulating dielectric layer 400 and the inorganic material layer 600 is simple and convenient, and may be carried out by one-time vapor evaporation; On the other hand, since when the insulating dielectric layer 400 is integrally formed with the inorganic material layer 600, the auxiliary cathode 500 is more stably disposed on the surface of the inorganic material layer 600, so that the auxiliary cathode 500 may better function to reduce the resistance of the metal traces in the display panel 10, and further effectively reduce the IR drop in the display panel 10.

According to an embodiment of the present invention, materials for forming the insulating dielectric layer 400 and the inorganic material layer 600 each independently include at least one of silicon oxide, silicon nitride and silicon oxynitride. Therefore, the materials are widely available and low in cost. Meanwhile, the insulating dielectric layer 400 and the inorganic material layer 600 are suitable to be formed by a one-time patterning process or one-time vapor evaporation during manufacturing, and the operation is simple, convenient, easy to carry out and easy for industrial production.

According to an embodiment of the present invention, the thicknesses of the insulating dielectric layer 400 and the inorganic material layer 600 are independently 1000-4000 Å (it should be noted that all numerical ranges described in the present invention may be up and down by 5%. That is, values higher than the upper limit of the numerical range and lower than the lower limit of the numerical range by 5%, should still be within the protection scope of the present invention and this will not be repeated hereinafter). In some embodiments of the present invention, in particular, the thicknesses of the insulating dielectric layer 400 and the inorganic material layer 600 may be independently 1000 Å, 2000 Å, 3000 Å, or 4000 Å. As a result, the thicknesses of the insulating dielectric layer 400 and the inorganic material layer 600 are appropriate, which may effectively achieve the functions of preventing the light-emitting layer 303 from bending after the manufacture and stabilizing the mutual bonding between the auxiliary cathode 500 and the inorganic material layer 600.

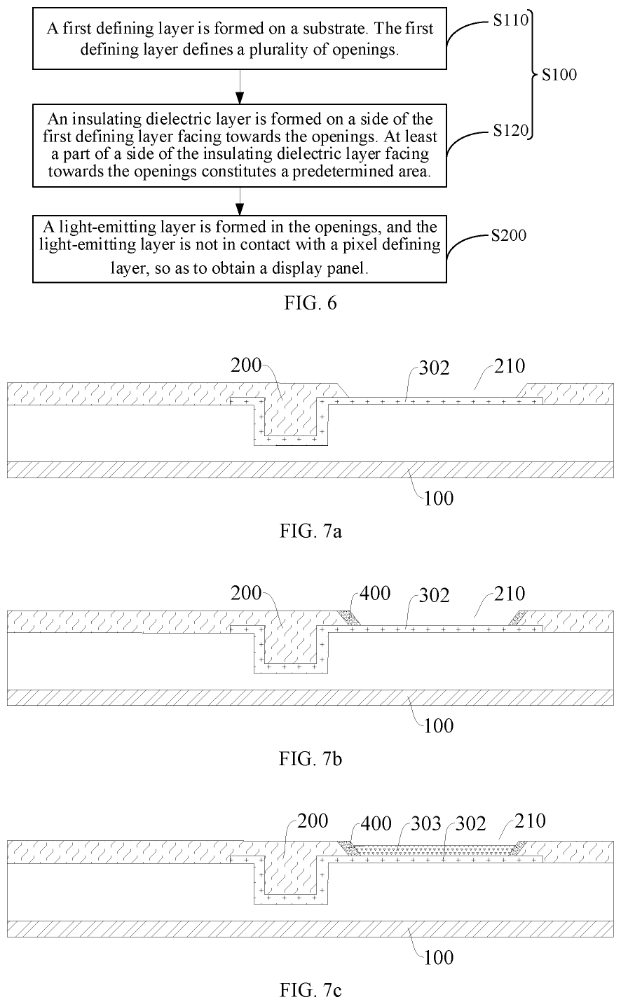

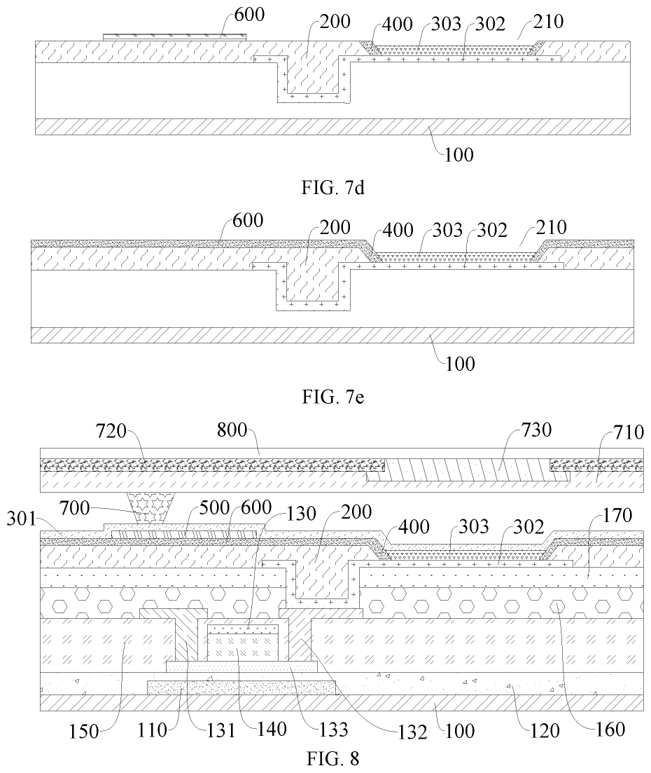

In another aspect of the present invention, the present invention provides a method for manufacturing the aforementioned display panel. According to an embodiment of the present invention, referring to FIG. 6 and FIG. 7a to FIG. 7c, the method includes steps S100 and S200.

Step S100: A pixel defining layer defining a plurality of openings 210 is formed on a substrate. The pixel defining layer includes a predetermined area on a side facing towards the openings. Hydrophilicity at each position of the predetermined area is made to be substantially identical (according to the above, it may be rephrased as that: hydrophilicity of the pixel defining layer at each position of the predetermined area is made to be substantially identical).

According to an embodiment of the present invention, in particular, forming the pixel defining layer may include steps S110 and S120.

Step S110: A first defining layer 200 is formed on the substrate 100. The first defining layer 200 defines a plurality of the openings 210 (refer to FIG. 7a for a schematic structural diagram).

According to an embodiment of the present invention, the specific process for forming the first defining layer 200 defining a plurality of openings 210 on the substrate 100 is not particularly limited, and may be vapor evaporation or carried out by a patterning process, for example. As a result, the operation is simple, convenient, easy to carry out and easy for industrial production.

Step S120: An insulating dielectric layer 400 is formed on a side of the first defining layer 200 facing towards the openings 210. At least a part of a side of the insulating dielectric layer 400 facing towards the openings constitutes the predetermined area (refer to FIG. 7b for a schematic structural diagram).

According to an embodiment of the present invention, as described above, the insulating dielectric layer 400 may be formed by vapor evaporation, which will not be repeated here. Therefore, the operation is simple, convenient, easy to carry out and easy for industrial production.

Step S200: a light-emitting layer 303 is formed in the openings 210, and the light-emitting layer 303 covers the predetermined area, so as to obtain the display panel (refer to FIG. 7c for a schematic structural diagram).

According to an embodiment of the present invention, the process for forming the light-emitting layer 303 may be ink-jet printing. As described above, in the display panel, the light-emitting layer 303 is in contact with the insulating dielectric layer 400, instead of the first defining layer 200. The hydrophilicity at each position on a surface of the insulating dielectric layer 400 away from the first defining layer 200 is substantially identical, so there is no problem of the surface hydrophobicity and hydrophilicity being different. Therefore, the light-emitting layer 303 in the display panel may not bend after manufacture, and the uniformity of the thickness of the light-emitting layer 303 is high, so that the brightness uniformity of light emitted by the display panel is good, and the problem that the light-emitting layer 303 overflows from the openings during manufacture may not occur. As a result, the phenomenon of electric leakage or the brightness in the periphery of the pixel unit may not occur during the use of the display panel, thereby the display effect of the display panel is good.

According to an embodiment of the present invention, referring to FIG. 7d and FIG. 7e, the method further includes forming an inorganic material layer 600 on a surface of the first defining layer 200 away from the substrate 100 (S400); forming an auxiliary cathode on a surface of the inorganic material layer 600 away from the first defining layer 200 (S500, not shown in the figures); forming a cathode on a surface of the auxiliary cathode away from the substrate (S600, not shown in the figures). The timing for implementing S400 is not limited, which may be carried out simultaneously with S200, before S200, after S200, or even after S300.

According to an embodiment of the present invention, as described above, the inorganic material layer 600 may be formed by vapor evaporation, which will not be repeated here.

In some specific embodiments of the present invention, the insulating dielectric layer 400 and the inorganic material layer 600 are formed in one step. Therefore, the operation is simple, convenient, easy to carry out and easy for industrial production.

According to an embodiment of the present invention, furthermore, when the insulating dielectric layer 400 and the inorganic material layer 600 are formed in one step, they may be formed by a one-time patterning process (refer to FIG. 7d for a schematic structural diagram). Alternatively, the insulating dielectric layer 400 and the inorganic material layer 600 may be formed simultaneously by means of vapor evaporation, and the formed insulating dielectric layer 400 is integrally formed with the inorganic material layer 600 (refer to FIG. 7e for a schematic structural diagram). As a result, after the auxiliary cathode is formed, the auxiliary cathode 500 is more stably disposed on a surface of the inorganic material layer 600, so that the auxiliary cathode 500 may better function to reduce the resistance of the metal traces in the display panel 10, and further effectively reduce the IR drop in the display panel 10. Meanwhile, the process is simple and convenient, easy to achieve industrialization, and the production efficiency of the display panel is significantly improved.

In yet another aspect of the present invention, the present invention provides a display apparatus. According to an embodiment of the present invention, referring to FIG. 8, the display apparatus includes the aforementioned display panel. The display apparatus when in use does not have the phenomenon of electric leakage or the brightness in the periphery of the pixel unit, so as to have good display effect and all the features and advantages of the display panel described above, which will not be repeated here.

According to an embodiment of the present invention, referring to FIG. 8, in addition to the aforementioned display panel, the display apparatus further includes a spacer wall 700, a planarization layer 710, a black matrix 720, a color filter 730, and a cover glass 800. The positions of arrangement and connection relationships of the above structures and components are conventional positions of arrangement and connection relationships, which will not be repeated here.

According to an embodiment of the present invention, the display apparatus may be formed by sequentially depositing the black matrix 720, the color filter 730, the planarization layer 710 and the spacer wall 700 on the cover glass 800, and then aligning and press-fitting to the aforementioned display panel. Therefore, the operation is simple, convenient, easy to carry out and easy for industrial production.

According to an embodiment of the present invention, in particular, an OLED device in the display apparatus may be either a top emission OLED device or a bottom emission OLED device. When the OLED device in the display apparatus may be a top emission OLED device, the display apparatus is provided with a higher aperture ratio and better display effect.

In the description of the present invention, it should be noted that unless otherwise clearly specified and defined, that the first feature is “on” or “under” the second feature may be that the first and second features are in direct contact, or the first and second features are in indirect contact through an intermediary. Moreover, that the first feature is “over”, “above” and “on” the second feature may be that the first feature is directly above or obliquely above the second feature, or simply means that a horizontal height of the first feature is higher than that of the second feature. That the first feature is “below”, “beneath” and “under” the second feature may be that the first feature is directly below or obliquely below the second feature, or simply means that the horizontal height of the first feature is less than that of the second feature.

In the description of this specification, the description with reference to the terms “an embodiment,” “some embodiments,” “examples,” “specific examples,” or “some examples” and the like means that a specific feature, structure, material, or characteristic described in connection with the embodiment or example is included in at least one embodiment or example of the present invention. In this specification, the schematic representation of the above-mentioned terms is not necessarily directed to the same embodiment or example. Moreover, the specific feature, structure, material, or characteristic described may be combined in any one or more embodiments or examples in a proper way. In addition, those skilled in the art may incorporate and combine different embodiments or examples and features of different embodiments or examples described in this specification if there is no conflict.

Although embodiments of the present invention have been shown and described above, it is to be understood that the above-mentioned embodiments are exemplary and should not be construed as limiting the present invention, and those of ordinary skilled in the art may make changes, modifications, substitutions and variations to the above-mentioned embodiments within the scope of the present invention.

1. A display panel comprising a substrate, a light-emitting element and a pixel defining layer, wherein the light-emitting element comprises a cathode, an anode and a light-emitting layer, the pixel defining layer defines a plurality of openings, the light-emitting layer is disposed in the openings and covers a predetermined area on a side of the pixel defining layer facing towards the openings, and hydrophilicity of the pixel defining layer at each position of the predetermined area is substantially identical.

2. The display panel of claim 1, wherein the pixel defining layer comprises:
a first defining layer defining a plurality of the openings; and
an insulating dielectric layer disposed on a side of the first defining layer facing towards the openings, wherein at least a part of a side of the insulating dielectric layer facing towards the openings constitutes the predetermined area.

3. The display panel of claim 2, further comprising:
an auxiliary cathode disposed on a surface of the cathode close to the substrate; and
an inorganic material layer, wherein the inorganic material layer is disposed on a surface of the auxiliary cathode close to the substrate, and a surface of the inorganic material layer away from the auxiliary cathode is in contact with a surface of the first defining layer away from the substrate.

4. The display panel of claim 3, wherein the insulating dielectric layer is integrally formed with the inorganic material layer.

5. The display panel of claim 3, wherein materials for forming the insulating dielectric layer and the inorganic material layer each independently comprise at least one of silicon oxide, silicon nitride and silicon oxynitride.

6. The display panel of claim 3, wherein thicknesses of the insulating dielectric layer and the inorganic material layer each are independently 1000-4000 Å.

7. A method for manufacturing the display panel of claim 1, comprising:
forming a pixel defining layer defining a plurality of openings on a substrate, providing a predetermined area on a side of the pixel defining layer facing towards the openings, making hydrophilicity of the pixel defining layer at each position of the predetermined area to be substantially identical; and
forming a light-emitting layer in the openings, wherein the light-emitting layer covers the predetermined area, so as to obtain the display panel.

8. The method of claim 7, wherein forming the pixel defining layer comprises:
forming a first defining layer on the substrate, wherein the first defining layer defines a plurality of openings; and
forming an insulating dielectric layer on a side of the first defining layer facing towards the openings, wherein at least a part of a side of the insulating dielectric layer facing towards the openings constitutes the predetermined area.

9. The method of claim 8, further comprising:
forming an inorganic material layer on a surface of the first defining layer away from the substrate;
forming an auxiliary cathode on a surface of the inorganic material layer away from the first defining layer; and
forming a cathode on a surface of the auxiliary cathode away from the substrate.

10. The method of claim 9, wherein the insulating dielectric layer and the inorganic material layer are formed in one step.

11. A display apparatus comprising the display panel of claim 1.

12. The display panel of claim 4, wherein materials for forming the insulating dielectric layer and the inorganic material layer each independently comprise at least one of silicon oxide, silicon nitride and silicon oxynitride.

13. The display panel of claim 4, wherein thicknesses of the insulating dielectric layer and the inorganic material layer each are independently 1000-4000 Å.

14. The display panel of claim 5, wherein thicknesses of the insulating dielectric layer and the inorganic material layer each are independently 1000-4000 Å.
